(19) United States
(12) Patent Application Publication
(10) Pub. No.: US 2026/0362889 A1
(43) Pub. Date: Nov. 12, 2026

(54) OPTICAL TRANSMISSION ELEMENT

(71) Applicant: National Chung Hsing University, Taichung City (TW)

(72) Inventor: CHIA-FENG LIN, Taichung City (TW)

(73) Assignee: National Chung Hsing University, Taichung City (TW)

(21) Appl. No.: 19/205,947

(22) Filed: May 12, 2025

(51) Int. Cl. H10H 29/856; G02B 6/12

(52) U.S. Cl. CPC H10H 29/856; G02B 6/12004

(57) ABSTRACT

An optical transmission element includes a substrate and at least one optical transmission module formed above the substrate. The at least one optical transmission module includes a first reflective layer located above the substrate, a light-emitting diode layer formed above the first reflective layer, and a second reflective layer formed above the light-emitting diode layer. An emission area, an optical waveguide area, and an optical detection area are defined as being arranged sequentially along a direction of a lateral reference line. Each of the emission area, the optical waveguide area, and the optical detection area includes the first reflective layer, the light-emitting diode layer, and the second reflective layer. Light emitted from the light-emitting diode layer of the emission area is propagated between the first reflective layer and the second reflective layer, and guided through the optical waveguide area to the optical detection area.

### BACKGROUND OF THE INVENTION

### Technical Field

The present invention relates to optical communication, and more particularly to an optical transmission element capable of reducing optical loss.

### Description of Related Art

It is known that with the continuous growth in data transmission demands, traditional copper wire and optical fiber technologies have gradually revealed their limitations, such as low transmission efficiency and high structural costs. Therefore, optical communication technology has been widely applied as a replacement for traditional copper wire or optical fiber transmission.

Generally, an optical transmission device transmits an optical signal into an optical fiber by coupling one end of the optical fiber to a light source of a light-emitting diode (LED), for example. The other end of the optical fiber is coupled to a photodiode (PD), for example, to detect the optical signal. However, during signal transmission, optical loss tends to occur at an interface between the optical fiber and the light-emitting diode, or at an interface between the optical fiber and the photodiode. Accordingly, providing an optical transmission element capable of reducing such optical loss remains an urgent issue to be addressed.

### BRIEF SUMMARY OF THE INVENTION

In view of the above, the primary objective of the present invention is to provide an optical transmission element capable of reducing optical loss.

The present invention provides an optical transmission element including a substrate and at least one optical transmission module. The at least one optical transmission module is formed above the substrate and includes a first reflective layer located above the substrate, a light-emitting diode layer formed above the first reflective layer, and a second reflective layer formed above the light-emitting diode layer. An emission area, an optical waveguide area, and an optical detection area are defined as being arranged sequentially along a direction of a lateral reference line. Each of the emission area, the optical waveguide area, and the optical detection area includes the first reflective layer, the light-emitting diode layer, and the second reflective layer. In this way, light emitted from the light-emitting diode layer of the emission area is propagated between the first reflective layer and the second reflective layer, and guided through the optical waveguide area to the optical detection area.

Through the design in which the first reflective layer, the light-emitting diode layer, and the second reflective layer of the emission area, the optical waveguide area, and the optical detection area are formed continuously without any interface between them, the light emitted by the emission area of each optical transmission module could be propagated between the first reflective layer and the second reflective layer of each optical transmission module, and guided by the optical waveguide area to the optical detection area of each optical transmission module. In this way, optical loss generated during light transmission could be effectively reduced.

### BRIEF DESCRIPTION OF THE SEVERAL VIEWS OF THE DRAWINGS

The present invention would be best understood by referring to the following detailed description of some illustrative embodiments in conjunction with the accompanying drawings, in which

FIG. 1 is a schematic view of the optical transmission device according to an embodiment of the present invention;

FIG. 2 is a sectional view along the A-A line in FIG. 1;

FIG. 3 is a sectional view along the B-B line in FIG. 1;

FIG. 4 is a schematic view of the optical transmission device according to the embodiment of the present invention, showing an application of the optical transmission device;

FIG. 5 is a schematic view of the optical transmission element according to another embodiment of the present invention;

FIG. 6 is a sectional view along the C-C line in FIG. 5.

### DETAILED DESCRIPTION OF THE INVENTION

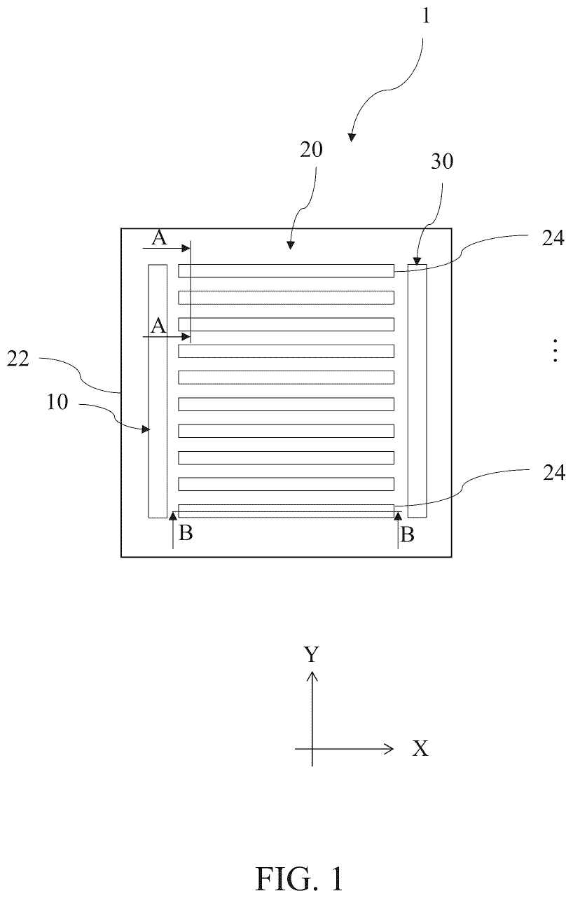

An optical transmission device 1 according to an embodiment of the present invention is illustrated in FIG. 1 to FIG. 4 and includes a driving element 10, an optical transmission element 20, and a power element 30.

As shown in FIG. 1, the optical transmission element 20 includes a substrate 22 and a plurality of optical transmission modules 24. A lateral reference line X and a longitudinal reference line Y, which are perpendicular to each other, are defined. The optical transmission modules 24 are spaced apart and arranged along a direction of the longitudinal reference line Y. The optical transmission modules 24 are formed above the substrate 22. The substrate 22, for example, might be a sapphire substrate, a silicon substrate, a silicon carbide substrate, a gallium arsenide substrate, an indium phosphide substrate, or a glass substrate.

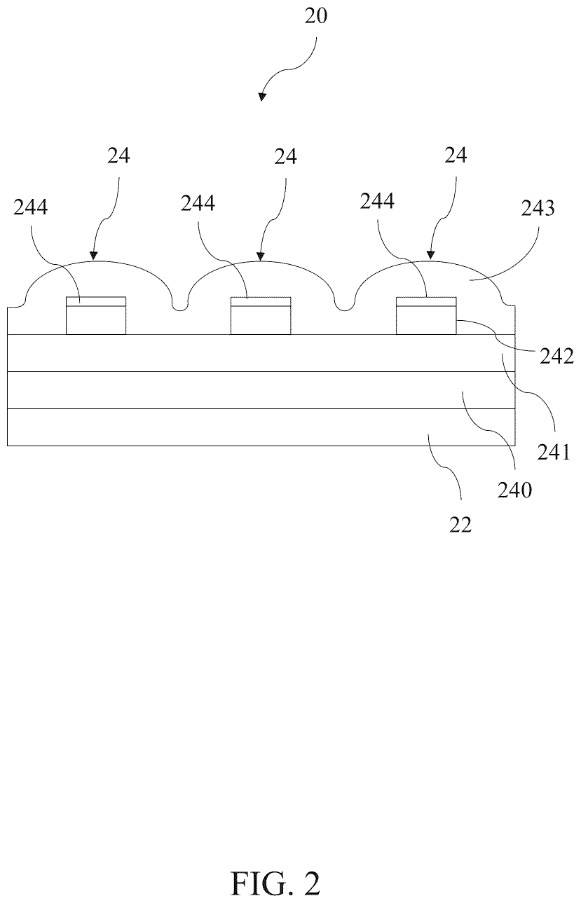

As shown in FIG. 2, the optical transmission element 20 includes a buffer layer 240, a first reflective layer 241, a light-emitting diode layer 242, and a second reflective layer 243, which are stacked on one another. Each optical transmission module 24 includes the first reflective layer 241, the light-emitting diode layer 242, and the second reflective layer 243. The buffer layer 240 is formed above the substrate 22. Each optical transmission module 24 is formed above the buffer layer 240. The buffer layer 240, for example, might be an undoped GaN layer. The first reflective layer 241 is formed on the buffer layer 240 and is located above the substrate 22. The first reflective layer 241 is a porous reflective layer. For example, the first reflective layer 241 might be a distributed Bragg reflector (DBR), and the first reflective layer 241 is the porous reflective layer formed through electrochemical wet etching.

The light-emitting diode layer 242 is formed above the first reflective layer 241. The light-emitting diode layer 242, for example, could include a N-type AlGaInN sublayer doped with silicon, an InGaN light-emitting sublayer, and a P-type AlGaInN sublayer doped with magnesium, which are stacked on one another. In other embodiments, the light-emitting diode layer 242 could include a plurality of light-emitting structure. The light-emitting structure are stacked vertically and capable of emitting wavelengths ranging from ultraviolet to infrared light. For example, the light-emitting structures could include a blue light-emitting structure, a green light-emitting structure, and a red light-emitting structure, which are vertically stacked on one another. The blue light-emitting structure is able to emit blue light, the green light-emitting structure is able to emit green light, and the red light-emitting structure is able to emit red light.

The second reflective layer 243 is formed above the light-emitting diode layer 242. The second reflective layer 243 covers a top portion and a side portion of the light-emitting diode layer 242 located in an emission area A1, an optical waveguide area A2, and an optical detection area A3, thus forming a closed elongated optical waveguide structure. The second reflective layer 243 might be a SiO₂/TiO₂ dielectric distributed Bragg reflector. In the current embodiment, a light-transmitting conductive layer 244 is deposited between the second reflective layer 243 and the light-emitting diode layer 242. For example, the light-transmitting conductive layer 244 might be an Indium Tin oxides (ITO) layer.

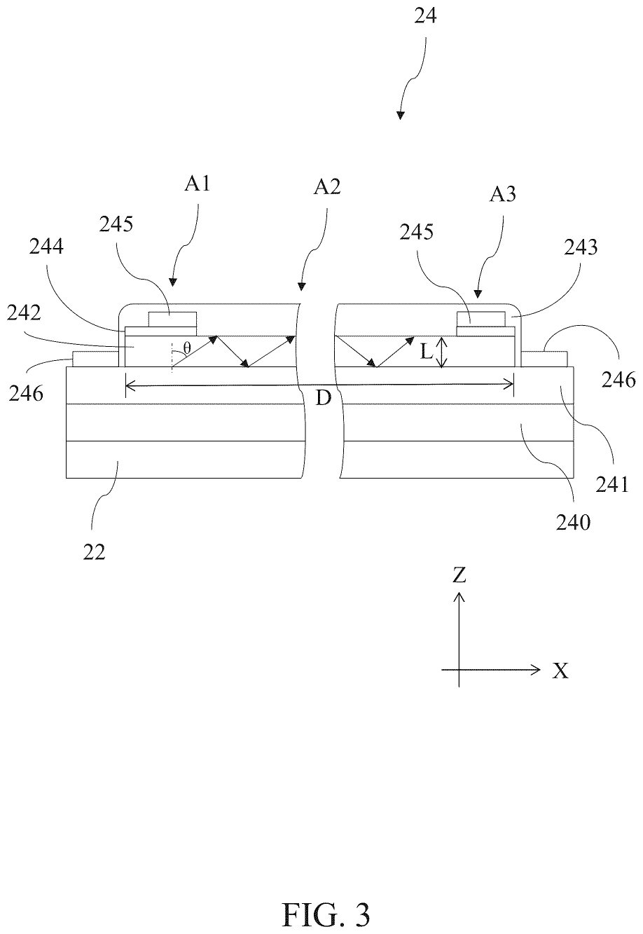

As shown in FIG. 3, the emission area A1, the optical waveguide area A2, and the optical detection area A3 are defined as being arranged sequentially along a direction of the lateral reference line X. Each of the emission area A1, the optical waveguide area A2, and the optical detection area A3 includes the first reflective layer 241, the light-emitting diode layer 242, and the second reflective layer 243. The emission area A1 includes a micro resonant-cavity light-emitting source (μ-RC-LED), and the optical detection area A3 includes a micro resonant-cavity photodetector element (μ-RC-PD). The optical waveguide area A2 has a length D along the direction of the lateral reference line X, wherein the length D is greater than or equal to 200 μm and less than or equal to 30 cm. The light-transmitting conductive layer 244 is located between the second reflective layer 243 of emission area A1 and the light-emitting diode layer 242 of emission area A1, and is located between the second reflective layer 243 of the optical detection area A3 and the light-emitting diode layer 242 of the optical detection area A3. A P-type electrode 245 is disposed above the light-transmitting conductive layer 244 of the emission area A1 and the light-transmitting conductive layer 244 of the optical detection area A3. The N-type AlGaInN sublayer doped with silicon of the emission area A1 and the N-type AlGaInN sublayer doped with silicon of the optical detection area A3 are respectively electrically connected to an N-type electrode 246.

Through semiconductor processing, the buffer layer 240, the first reflective layer 241, the light-emitting diode layer 242, and the second reflective layer 243 could be formed above the substrate 22, and the optical transmission modules 24 arranged in an array are then defined. Therefore, light emitted from the light-emitting diode layer 242 of the emission area A1 is propagated between the first reflective layer 241 and the second reflective layer 243, wherein the light emitted from the light-emitting diode layer 242 of the emission area A1 is reflected between the first reflective layer 241 and the second reflective layer 243. The light emitted from the light-emitting diode layer 242 of the emission area A1 guided through the optical waveguide area A2 to the optical detection area A3. Through the design in which the first reflective layer 241, the light-emitting diode layer 242, and the second reflective layer 243 of the emission area A1, the optical waveguide area A2, and the optical detection area A3 are formed continuously without any interface between them, optical loss during the guiding of light through the optical waveguide area A2 from the light-emitting diode layer 242 of the emission area A1 to the optical detection area A3 could be significantly reduced. In the current embodiment, the plurality of optical transmission modules 24 are used as an example. In other embodiments, the optical transmission module 24 might also be one, and the single optical transmission module 24 could also achieve the same effect of guiding the light emitted from the light-emitting diode layer 242 of the emission area A1 through the optical waveguide area A2 to the optical detection area A3. Furthermore, the emission area A1 and the optical detection area A3 have the same structure of the first reflective layer 241, the light-emitting diode layer 242, and the second reflective layer 243. Accordingly, the light emitted from the emission area A1 could be transmitted to the optical detection area A3 through the optical waveguide area A2, and light emitted from the optical detection area A3 could be transmitted to the emission area A1 through the optical waveguide area A2, thereby enabling bidirectional optical transmission. The emission area A1 and the optical detection area A3 have the same structure, which could act as a light-emitting diode under an electrical forward bias condition and as a photodetector under an electrical reverse bias condition, enabling bidirectional optical transmission.

The driving element 10 is electrically connected to each optical transmission module 24 to drive the emission area A1 of each optical transmission module 24. The power element 30 is electrically connected to each optical transmission module 24 to receive a signal output from each optical transmission module 24. For example, the power element 30 might include an amplifier circuit element. Moreover, in the current embodiment, the driving element 10 and the power element 30 are formed on the substrate 22 through a semiconductor process. In other embodiments, the driving element 10 and the power element 30 are packaging bonded on the substrate 22 through a semiconductor process. An input signal of the driving element 10 is I/O signal, and an output signal of the power element 30 is also I/O signal. In this way, the driving element 10, the optical transmission modules 24, and the power element 30 could be formed on the substrate 22 within a single semiconductor process. In other embodiments, the optical transmission device 1 could also include a glass substrate. The driving element 10, the optical transmission element 20, and the power element 30 are individually fabricated and then disposed on the glass substrate, for example, using flip-chip packaging, which could replace a plurality of copper lines on the substrate 22 or on a wafer.

Moreover, a vertical reference line Z which is perpendicular to the lateral reference line X and the longitudinal reference line Y is defined. The light emitted from the light-emitting diode layer 242 of the emission area A1 has a wavelength λ. The light-emitting diode layer has an optical refractive index N, and n is a positive integer. A minimum distance L between the first reflective layer 241 and the second reflective layer 243 along the vertical reference line Z satisfies a condition of NL<3λ. A vertical optical resonant cavity might be formed between the first reflective layer 241 of the emission area A1 and the second reflective layer 243 of the emission area A1. Moreover, the light emitted from the light-emitting diode layer 242 of the emission area A1 has the wavelength λ. The light-emitting diode layer has an optical refractive index N, and n is a positive integer. The minimum distance L between the first reflective layer 241 and the second reflective layer 243 along the vertical reference line Z satisfies a condition of NL≠nλ/2. In this way, as shown in FIG. 3, an angle θ is provided between the light emitted by the light-emitting diode layer 242 of the emission area A1 and the vertical reference line Z. The angle θ is greater than 0°, thereby facilitating the propagation of the light emitted by the light-emitting diode layer 242 of the emission area A1 within the optical waveguide area A2.

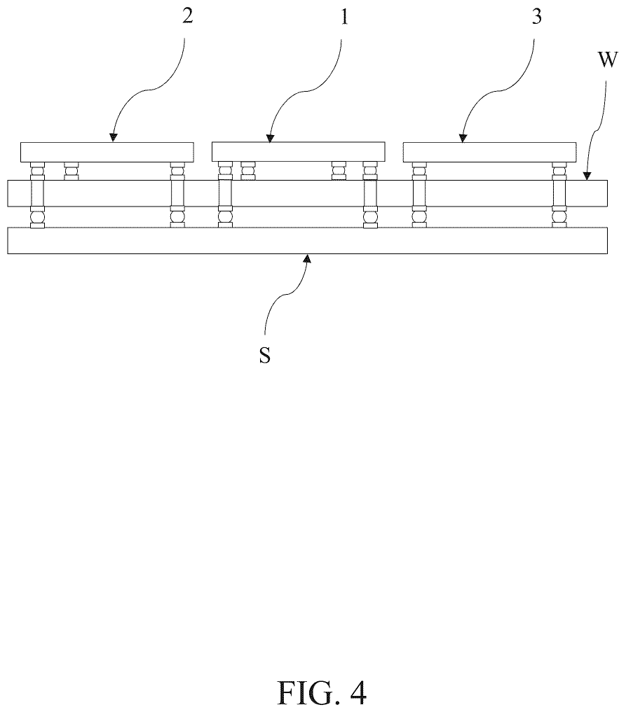

As shown in FIG. 4, for example, the CoWoS (Chip-on-Wafer-on-Substrate) packaging technology could be used to attach a processor chip 2, such as a GPU, CPU, NPU (XPU), a chip of the optical transmission device 1, and a high-bandwidth memory chip 3, such as HBM, onto a wafer W (e.g., an intermediate board, an Interposer, or a ABF substrate), forming a Chip-On-Wafer (CoW) structure. The Chip-On-Wafer (CoW) structure is then attached to a substrate, such as a printed circuit board (PCB), thereby forming a CoWoS structure. In this way, the micro resonant-cavity light-emitting source (μ-RC-LED) of the emission area A1 could be connected to the processor chip 2 through the driving element 10. The micro resonant-cavity photodetector element (μ-RC-PD) of the optical detection area A3 could be connected to the high-bandwidth memory chip 3 through the power element 30. Thus, a complete signal input and output structure is achieved.

In summary, through the design in which the first reflective layer 241, the light-emitting diode layer 242, and the second reflective layer 243 of the emission area A1, the optical waveguide area A2, and the optical detection area A3 are formed continuously without any interface between them, the light emitted by the emission area A1 of each optical transmission module 24 could be propagated between the first reflective layer 241 and the second reflective layer 243 of each optical transmission module 24, and guided by the optical waveguide area A2 to the optical detection area A3 of each optical transmission module 24. In this way, optical loss generated during light transmission could be effectively reduced.

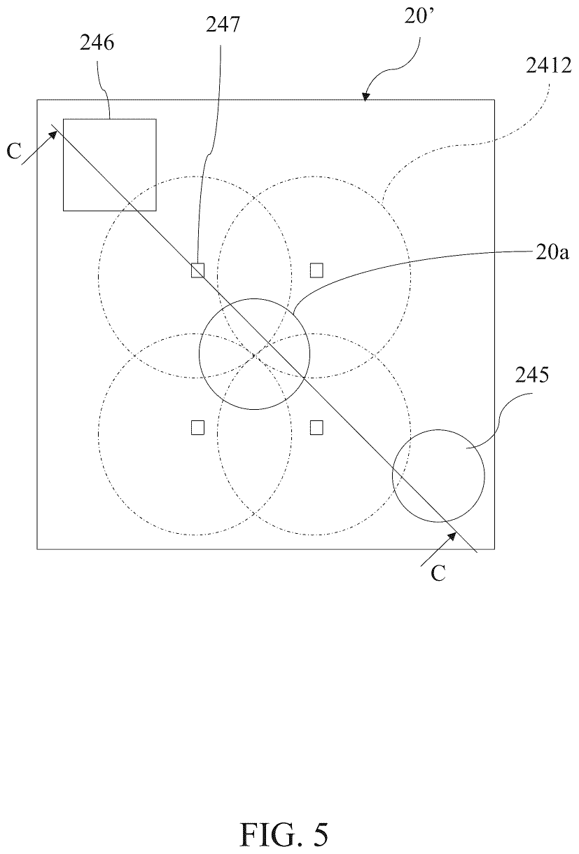

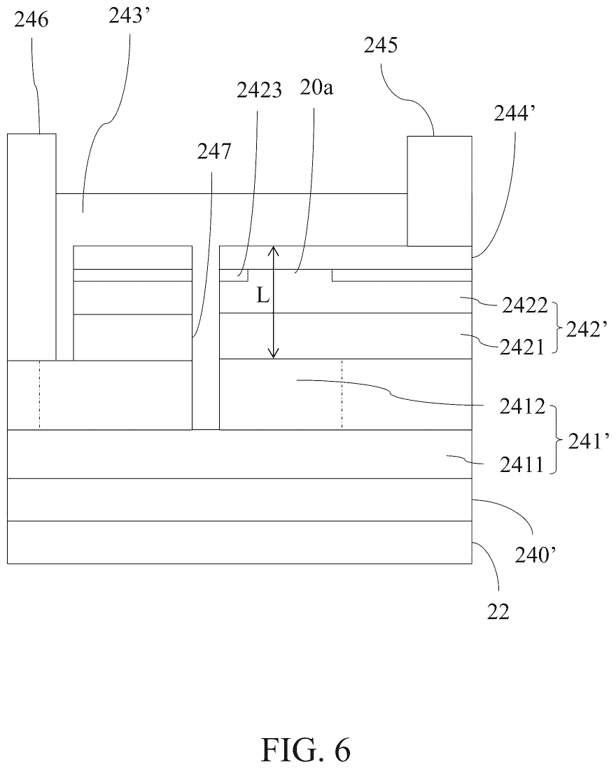

An optical transmission element 20′ according to another embodiment of the present invention is illustrated in FIG. 5 and FIG. 6. The optical transmission element 20′ includes a buffer layer 240′, a first reflective layer 241′, a light-emitting diode layer 242′, a light-transmitting conductive layer 244′, and a second reflective layer 243′, which are stacked on one another. The optical transmission element 20′ has a via-hole array 247. The first reflective layer 241′ could be a N-type semiconductor layer 2411. A reflector array 2412 is embedded in a local region of the N-type semiconductor layer 2411. An etching solution could contact the N-type semiconductor layer 2411 through the via-hole array 247, and electrochemical lateral etching is applied to form a porous reflective layer. The reflector array 2412 includes a distributed Bragg reflector with a periodic structure of porous conductive aluminum gallium nitride and low-silicon-doped aluminum gallium nitride. A porous reflector is formed in a region of the light-emitting aperture 20a of the optical transmission element 20′. A surface of the reflector array 2412 could be a structure of porous conductive aluminum gallium nitride. The surface of the reflector array 2412 which is porous spontaneously forms an insulating film including Aluminium oxide (AlOx) or Gallium oxide (GaOx). The insulating film is adapted to reduce the effective optical refractive index and suppress surface leakage issues in the first reflective layer 241. The first reflective layer 241′ could include a plurality of porous reflector having different central reflection wavelengths. The porous reflectors could cover a wavelength range from ultraviolet to visible light. For example, the first reflective layer 241′ might include the porous reflectors with central reflection wavelengths of 400 nm, 450 nm, 500 nm, 550 nm, and 620 nm. The porous reflectors having different central reflection wavelengths could be fabricated by adjusting the film stack thickness and etching conditions. Among the porous reflectors, the one whose central reflection wavelength matches both an emission wavelength range and a detected wavelength range of the light-emitting diode layer 242′ is formed closest to a lower portion of the light-emitting diode layer 242′.

The light-emitting diode layer 242′ and the light-transmitting conductive layer 244′ are formed above the first reflective layer 241′. The light-emitting diode layer 242′, for example, might include a InGaN quantum well light-emitting sublayer 2421, and a P-type AlGaInN sublayer 2422 doped with Mg, serving as a P-type semiconductor sublayer. The InGaN quantum well light-emitting sublayer 2421 and the P-type AlGaInN sublayer 2422 doped with Mg are stacked on one another. A vertical optical resonant cavity might be formed between the first reflective layer 241′ and the second reflective layer 243′. A structure of the vertical optical resonant cavity might include the light-emitting diode layer 242′ and the light-transmitting conductive layer 244′. A minimum distance L between the first reflective layer 241′ and the second reflective layer 243′ along a vertical reference line Z defines a length of the structure of the vertical optical resonant cavity. The structure of the vertical optical resonant cavity does not include an N-type semiconductor layer. The vertical reference line Z is defined, and the light emitted from the light-emitting diode layer 242′ has a wavelength λ. A minimum distance L between the first reflective layer 241′ and the second reflective layer 243′ along the vertical reference line Z satisfies a condition of NL<3λ. Moreover, the minimum distance L between the first reflective layer 241′ and the second reflective layer 243′ along the vertical reference line Z satisfies a condition of NL≠nλ/2, wherein the light-emitting diode layer 242′ has an optical refractive index N, and n is a positive integer. The light-transmitting conductive layer 244′ exhibits visible light transmittance, low electrical resistance, and a low optical absorption coefficient. An insulating structure 2423 having high resistance is formed at a peripheral region of the light-emitting aperture 20a through a P-type semiconductor layer of the P-type AlGaInN sublayer 2422. The insulating structure 2423 might be formed using techniques such as deposition of SiO₂/Si₃N₄ insulating films, ion implantation, or plasma bombardment.

The second reflective layer 243′ is formed above the light-emitting diode layer 242′. The second reflective layer 243′ covers a top portion and a side portion of the light-emitting diode layer 242′. The second reflective layer 243′ might be a distributed Bragg reflector formed by periodically stacking SiO₂/TiO₂ dielectric materials. In the current embodiment, the light-transmitting conductive layer 244′ is deposited between the second reflective layer 243 and the light-emitting diode layer 242′. For example, the light-transmitting conductive layer 244′ might be an ITO layer. The via-hole array 247 might be filled with dielectric materials formed of the second reflective layer 243′ to create an insulating reflector, or the via-hole array 247 might undergo ion implantation to achieve insulation, sidewall protection, and surface planarization, thereby avoiding plasma damage. The via-hole array 247 is distributed on the optical transmission element 20′ and serves as a channel for wet etching to form the porous reflectors. Using radially circular lateral etching, an array of porous reflectors is formed beneath the region of the light-emitting aperture 20a, wherein the porous reflectors are embedded and have locally conductive regions.

The first reflective layer 241′, the light-emitting diode layer 242′, the light-emitting aperture region 20a, the light-transmitting conductive layer 244′, and the second reflective layer 243′ are arranged along a direction of the vertical reference line Z. The N-type electrode 246 which is metal is in contact with the reflector array 2412, which is embedded in the local region of the N-type semiconductor layer 2411.

It must be pointed out that the embodiments described above are only some preferred embodiments of the present invention. All equivalent structures which employ the concepts disclosed in this specification and the appended claims should fall within the scope of the present invention.

What is claimed is:

1. An optical transmission element, comprising:
a substrate; and
at least one optical transmission module formed above the substrate; the at least one optical transmission module comprises a first reflective layer located above the substrate, a light-emitting diode layer formed above the first reflective layer, and a second reflective layer formed above the light-emitting diode layer;
wherein an emission area, an optical waveguide area, and an optical detection area are defined as being arranged sequentially along a direction of a lateral reference line; each of the emission area, the optical waveguide area, and the optical detection area comprises the first reflective layer, the light-emitting diode layer, and the second reflective layer; light emitted from the light-emitting diode layer of the emission area is propagated between the first reflective layer and the second reflective layer, and guided through the optical waveguide area to the optical detection area.

2. The optical transmission element as claimed in claim 1, wherein a longitudinal reference line perpendicular to the lateral reference line is defined; a number of the at least one optical transmission module is plural; the optical transmission modules are spaced apart and arranged along a direction of the longitudinal reference line; the emission area and the optical detection area have the same structure, so that the light emitted from the emission area is transmitted to the optical detection area through the optical waveguide area, and light emitted from the optical detection area is transmitted to the emission area through the optical waveguide area, thereby enabling bidirectional optical transmission.

3. The optical transmission element as claimed in claim 1, wherein the optical waveguide area has a length along the direction of the lateral reference line; the length is greater than or equal to 200 μm and less than or equal to 30 cm; the second reflective layer covers a top portion and a side portion of the light-emitting diode layer located in the emission area, the optical waveguide area, and the optical detection area, thus forming a closed elongated optical waveguide structure.

4. The optical transmission element as claimed in claim 1, wherein the light-emitting diode layer comprises a plurality of light-emitting structure; the light-emitting structure are stacked vertically and capable of emitting wavelengths ranging from ultraviolet to infrared light.

5. The optical transmission element as claimed in claim 1, wherein a vertical reference line perpendicular to the lateral reference line is defined; the light emitted from the light-emitting diode layer of the emission area has a wavelength λ; the light-emitting diode layer has an optical refractive index N, and n is a positive integer; a minimum distance L between the first reflective layer and the second reflective layer along the vertical reference line satisfies a condition of NL≠nλ/2; the minimum distance L between the first reflective layer and the second reflective layer along the vertical reference line satisfies a condition of NL<3λ.

6. The optical transmission element as claimed in claim 5, wherein the light-emitting diode layer does not comprise an N-type semiconductor layer; the first reflective layer is a N-type semiconductor layer, wherein a reflector array is embedded in a local region of the N-type semiconductor layer.

7. The optical transmission element as claimed in claim 1, further comprising a buffer layer and a light-transmitting conductive layer; the buffer layer is formed above the substrate, and the at least one optical transmission module is formed above the buffer layer; the light-transmitting conductive layer is located between the second reflective layer of the emission area and the light-emitting diode layer of the emission area, and is located between the second reflective layer of the optical detection area and the light-emitting diode layer of the optical detection area.

8. The optical transmission element as claimed in claim 1, wherein the second reflective layer covers a top portion and a side portion of the light-emitting diode layer.

9. The optical transmission element as claimed in claim 1, wherein the substrate is a sapphire substrate, a silicon substrate, a silicon carbide substrate, a gallium arsenide substrate, an indium phosphide substrate, or a glass substrate.

10. The optical transmission element as claimed in claim 1, further comprising a via-hole array and a light-emitting aperture; the first reflective layer comprises a plurality of porous reflector having different central reflection wavelengths, wherein the porous reflectors cover a wavelength range from ultraviolet to visible light; the via-hole array serves as a channel for wet etching process; through radially circular lateral etching, the porous reflectors are formed beneath a region of the light-emitting aperture, wherein the porous reflectors are embedded and have locally conductive regions.
